(19) United States
(12) Patent Application Publication
(10) Pub. No.: US 2024/0222309 A1
(43) Pub. Date: Jul. 4, 2024

(54) SEMICONDUCTOR PACKAGE

(71) Applicant: Samsung Electronics Co., Ltd., Suwon-si (KR)

(72) Inventor: Okgyeong Park, Suwon-si (KR)

(21) Appl. No.: 18/515,412

(22) Filed: Nov. 21, 2023

(30) Foreign Application Priority Data
Jan. 4, 2023 (KR) 10-2023-0001326

(51) Int. Cl. H01L 23/00; H01L 23/31; H01L 23/498

(52) U.S. Cl. CPC H01L 24/29; H01L 23/3157; H01L 23/49838; H01L 24/16; H01L 24/32; H01L 24/73; H01L 2224/16227; H01L 2224/26175; H01L 2224/32225; H01L 2224/73204

(57) ABSTRACT

The inventive concept provides a semiconductor package including a substrate including a passivation layer, a semiconductor chip mounted on the substrate, an underfill material layer between the semiconductor chip and the substrate, and a dam structure on the substrate and surrounding the semiconductor chip, wherein a lower portion of the dam structure is in contact with the passivation layer and is formed of a material that is the same as a material forming the passivation layer, and an upper surface of the dam structure includes a first segment at a first vertical level and a second segment at a second vertical level, wherein the second vertical level is different from the first vertical level.

### CROSS-REFERENCE TO RELATED APPLICATION

This application is based on and claims priority under 35 U.S.C. § 119 to Korean Patent Application No. 10-2023-0001326, filed on Jan. 4, 2023, in the Korean Intellectual Property Office, the disclosure of which is incorporated by reference herein in its entirety.

### BACKGROUND

The inventive concept relates to a semiconductor package.

As a method for filling a gap between a semiconductor chip and a mounting substrate, an underfill process using an underfill material has recently been used. The underfill material protects chip connection bumps disposed between the semiconductor chip and the mounting substrate from the external environment, and also serves to relieve stress caused by a difference in the coefficient of thermal expansion of the semiconductor chip and the mounting substrate. The occurrence of voids in the underfill material causes deterioration in the reliability of the underfill material and electronic products including the same, and thus, there is a demand for suppression of voids in the underfill material.

### SUMMARY

The inventive concept provides a semiconductor package with improved reliability.

According to an aspect of the inventive concept, there is provided a semiconductor package including a substrate including a passivation layer, a semiconductor chip mounted on the substrate, an underfill material layer between the semiconductor chip and the substrate, and a dam structure on the substrate and surrounding the semiconductor chip, wherein a lower portion of the dam structure is in contact with the passivation layer and includes the same material as the material of the passivation layer, and an upper surface of the dam structure includes a first segment having a first vertical level and a second segment having a second vertical level, wherein the second vertical level is different from the first vertical level.

According to another aspect of the inventive concept, there is provided a semiconductor package including a substrate, a semiconductor chip mounted on the substrate, an underfill material layer between the semiconductor chip and the substrate, and a dam structure including a ring-shaped lower dam surrounding the semiconductor chip and an upper dam on the lower dam, wherein the upper dam includes an eaves covering a gap between the lower dam and the semiconductor chip.

According to another aspect of the inventive concept, there is provided a semiconductor package including a substrate including a base layer, connection pads on the base layer, and a passivation layer on the base layer, chip connection bumps connected to the connection pads through openings of the passivation layer, a semiconductor chip connected to the chip connection bumps, an underfill material layer provided between the semiconductor chip and the substrate and surrounding the chip connection bumps, and a dam structure on the substrate and surrounding the semiconductor chip, the dam structure including a lower dam attached to the passivation layer and an upper dam on the lower dam, wherein the upper surface of the dam structure includes a plurality of segments having different vertical levels, the lower dam includes a first lower sidewall facing a first side of the semiconductor chip, a second lower sidewall facing a second side of the semiconductor chip, a third lower sidewall facing a third side of the semiconductor chip, and a fourth lower sidewall facing a fourth side of the semiconductor chip, the upper dam extends along at least one of the first lower sidewall, the second lower sidewall, and the third lower sidewall of the lower dam, and the lower dam, the upper dam, and the passivation layer include the same material as each other.

### BRIEF DESCRIPTION OF THE DRAWINGS

Embodiments of the inventive concept will be more clearly understood from the following detailed description taken in conjunction with the accompanying drawings in which:

FIG. 1 is a plan view illustrating a semiconductor package according to some embodiments;

FIG. 2 is a cross-sectional view taken along line II-II′ of FIG. 1;

FIG. 3 is a cross-sectional view taken along line III-III′ of FIG. 1;

FIGS. 4A to 4D are plan views each illustrating a semiconductor package according to embodiments;

FIGS. 5A and 5B are cross-sectional views illustrating a semiconductor package according to embodiments;

FIG. 6A is a plan view illustrating a semiconductor package according to embodiments;

FIG. 6B is a side view showing a portion of a dam structure according to embodiments;

FIG. 7 is a cross-sectional view illustrating a semiconductor package according to embodiments;

FIGS. 8A to 8J are cross-sectional views illustrating a method of manufacturing a semiconductor package, according to embodiments; and

FIGS. 9A to 9C are cross-sectional views illustrating a method of manufacturing a semiconductor package, according to embodiments.

### DETAILED DESCRIPTION OF THE EMBODIMENTS

Hereinafter, embodiments of the inventive concept are described in detail with reference to the accompanying drawings. The same reference numerals are used for similar components in the drawings even though they may not be identical, and descriptions already given for a component may be omitted when the description would be redundant.

In this specification, a vertical direction may be defined as the Z direction as shown in the drawings, and the horizontal direction may be defined as a direction perpendicular to the Z direction as shown in the drawings. A first horizontal direction and a second horizontal direction may be defined as directions crossing each other and may be perpendicular to one another. The first horizontal direction may be referred to as the X direction as shown in the drawings, and the second horizontal direction may be referred to as the Y direction as shown in the drawings. A vertical level as used herein may refer to a height level in the vertical direction (Z direction) and may refer to a distance between a reference point, such as a base of an object, and a point being described. A horizontal width of an element may refer to a length of an element in a horizontal direction such as the X direction or the Y direction, and the vertical length of an element may refer to a length in the vertical direction (Z direction). The use of the X, Y, and Z directions are provided as a reference in describing the drawings and embodiments are not limited to the orientations referred to in the drawings.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

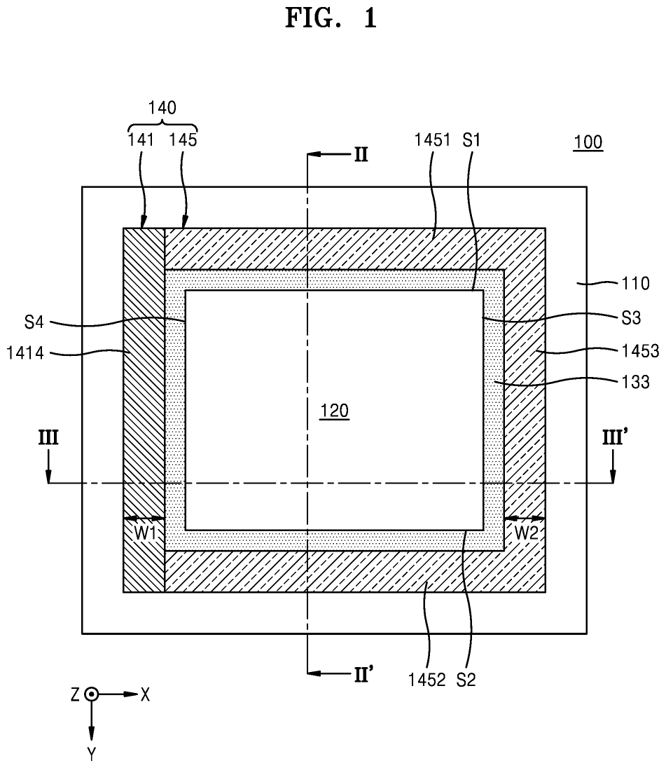

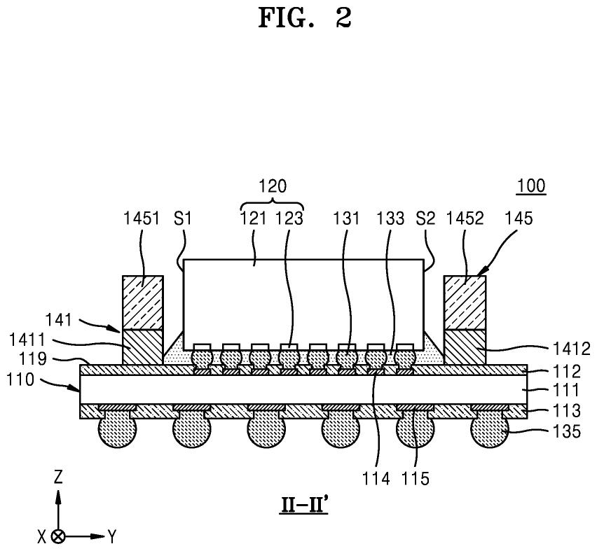

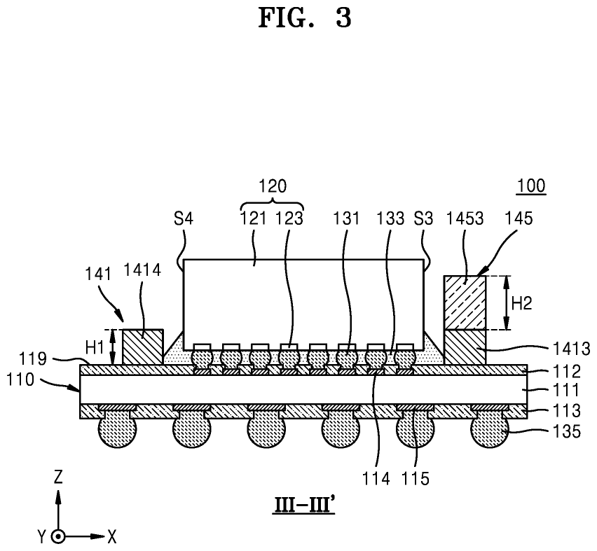

FIG. 1 is a plan view illustrating a semiconductor package 100 according to some embodiments. FIG. 2 is a cross-sectional view taken along line II-II′ of FIG. 1. FIG. 3 is a cross-sectional view taken along line III-III′ of FIG. 1.

Referring to FIGS. 1 to 3, the semiconductor package 100 may include a mounting substrate 110, a semiconductor chip 120, an underfill material layer 133, and a dam structure 140.

The mounting substrate 110 may have a flat plate shape or a panel shape (e.g., may have a low vertical length relative to a horizontal length). The mounting substrate 110 may include an upper surface 119 and a lower surface that are opposite to each other, and the upper surface 119 and the lower surface may each be flat. The upper surface 119 of the mounting substrate 110 may be parallel to the first horizontal direction (X direction) and the second horizontal direction (Y direction). The mounting substrate 110 may be a printed circuit board (PCB) or an interposer substrate. The mounting substrate 110 may be simply referred to as a substrate.

The mounting substrate 110 may include a base layer 111, upper connection pads 114, lower connection pads 115, an upper passivation layer 112, and a lower passivation layer 113.

The base layer 111 may be formed of and/or include at least one material selected from the group including phenol resin, epoxy resin, and polyimide. For example, the base layer 111 may include at least one material selected from the group including polyimide, flame retardant 4 (FR-4), tetrafunctional epoxy, polyphenylene ether, epoxy/polyphenylene oxide, bismaleimide triazine (BT), thermount, cyanate ester, and liquid crystal polymer.

The various pads of a device described herein may be conductive terminals connected to

internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may generally have a planar surface area (often larger than a corresponding surface area of the internal wiring to which they are connected) to promote connection to a further terminal, such as a bump or solder ball, and/or an external wiring.

The upper connection pads 114 may be provided on the upper surface of the base layer 111, and the lower connection pads 115 may be disposed on a lower surface of the base layer 111. An internal wiring configured to electrically connect the upper connection pads 114 to the lower connection pads 115 may be provided inside the base layer 111. The upper connection pads 114 and the lower connection pads 115 may be formed of and/or include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof.

The upper passivation layer 112 may be disposed on an upper surface of the base layer 111, and the lower passivation layer 113 may be disposed on a lower surface of the base layer 111. The upper passivation layer 112 may be formed to cover the upper surface of the base layer 111 and may cover a portion of each upper connection pad 114. The upper passivation layer 112 may include upper openings exposing the upper connection pads 114. The lower passivation layer 113 may be formed to cover the lower surface of the base layer 111 and may cover portions of each lower connection pad 115. The lower passivation layer 113 may include lower openings exposing the lower connection pads 115. The upper passivation layer 112 and the lower passivation layer 113 may be formed of, for example, solder resist.

Connection terminals 135 may be respectively attached to the lower connection pads 115 of the mounting substrate 110. The connection terminals 135 may be connected to the lower connection pads 115 through lower openings of the lower passivation layer 113. The connection terminals 135 may be configured to electrically and physically connect the mounting substrate 110 to an external device on which the mounting substrate 110 is mounted. The connection terminals 135 may be formed from, for example, solder balls or solder bumps.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes.

The semiconductor chip 120 may be mounted on the mounting substrate 110. The semiconductor chip 120 may include a semiconductor substrate 121 and a chip pad 123. The semiconductor substrate 121 may include upper and lower surfaces that are opposite to each other. The lower surface of the semiconductor substrate 121 may be an active surface of the semiconductor substrate 121, and the upper surface of the semiconductor substrate 121 may be an inactive surface of the semiconductor substrate 121. The semiconductor substrate 121 may be formed from a portion of a semiconductor wafer. The semiconductor substrate 121 may be formed of and/or include, for example, silicon (Si). Alternatively, the semiconductor substrate 121 may be formed of and/or include a semiconductor material, such as germanium (Ge) or a compound semiconductor, such as silicon carbide (SiC), gallium arsenide (GaAs), indium arsenide (InAs), and indium phosphide (InP). The semiconductor substrate 121 may include a conductive region, for example, a well doped with impurities or a structure doped with impurities. A semiconductor device layer including individual devices may be provided on or at the active surface of the semiconductor substrate 121. The individual devices may include, for example, transistors. The individual devices may include microelectronic devices, for example, image sensors such as metal-oxide-semiconductor field effect transistors (MOSFETs), large scale integration (LSIs), CMOS imaging sensors (CIS), etc., micro-electro-mechanical systems (MEMS), active devices, passive devices, and the like. The chip pad 123 is provided in or at the lower surface of the semiconductor chip 120 and may be electrically connected to the individual devices of the semiconductor device layer.

The semiconductor chip 120 may be mounted on the mounting substrate 110 in a flip chip method. The semiconductor chip 120 may be electrically and physically connected to the mounting substrate 110 through chip connection bumps 131. The chip connection bumps 131 may be respectively attached to chip pads 123 of the semiconductor chip 120 and the upper connection pads 114 of the mounting substrate 110. The chip connection bumps 131 may include solder bumps. The semiconductor chip 120 may be disposed on a chip mounting area of the mounting substrate 110 defined by being surrounded by the dam structure 140. In the semiconductor package 100, electronic components such as passive components may be mounted on another area of the mounting substrate 110 outside the dam structure 140.

In example embodiments, the semiconductor chip 120 may be a memory chip. The memory chip may be a volatile memory, such as dynamic random access memory (DRAM) and static random access memory (SRAM), or a non-volatile memory, such as phase-change random access memory (PRAM), magnetic random access memory (MRAM), ferroelectric random access memory (FeRAM), and resistive random access memory (RRAM). In example embodiments, the semiconductor chip 120 may be a logic chip. The logic chip may be a central processing unit (CPU) chip, a graphics processing unit (GPU) chip, an application processor (AP) chip, or an application specific integrated circuit (ASIC) chip.

The underfill material layer 133 may be between the semiconductor chip 120 and the mounting substrate 110. The underfill material layer 133 may fill a gap between the semiconductor chip 120 and the mounting substrate 110 and may surround the chip connection bumps 131. A portion of the underfill material layer 133 may extend outward from the side surface of the semiconductor chip 120. A portion of the underfill material layer 133 may contact a lower portion of each side surface of the semiconductor chip 120. The underfill material layer 133 may include an epoxy resin. For example, the underfill material layer 133 may be formed through a capillary under-fill process. In some embodiments, the underfill material layer 133 may be formed of and/or include a non-conductive film.

The dam structure 140 may be disposed on the mounting substrate 110. The dam structure 140 may be attached to the upper passivation layer 112 of the mounting substrate 110. The dam structure 140 may extend horizontally to surround the semiconductor chip 120 on the upper surface 119 of the mounting substrate 110. The dam structure 140 may have a ring shape surrounding the semiconductor chip 120. For example, the dam structure 140 may have a square ring shape. For example, when the semiconductor chip 120 has first to fourth side surfaces S1, S2, S3, and S4, the dam structure 140 may extend along an imaginary square line (e.g., a square larger in size than the semiconductor chip) surrounding the semiconductor chip 120. The dam structure 140 blocks the flow of the underfill material during an underfill process of forming the underfill material layer 133, thereby controlling the final shape of the underfill material layer 133 and limiting an area where the underfill material layer 133 is formed to an area surrounded by the dam structure 140.

The dam structure 140 may be made of, formed of, and/or include an insulating material. For example, the dam structure 140 may be formed of and/or include solder resist, epoxy resin, and/or polyimide. In example embodiments, at least a portion of the dam structure 140 may be formed of the same material as the material forming the upper passivation layer 112 of the mounting substrate 110. For example, a lower portion of the dam structure 140 may contact the upper passivation layer 112 and be formed of the same material as the material forming the upper passivation layer 112 (e.g., solder resist). Bonding force (e.g., adhesion) between components including the same material may be greater than bonding force (e.g., adhesion) between components including different materials. According to example embodiments, the dam structure 140 may include the same material as the material forming the upper passivation layer 112, adhesion between the dam structure 140 and the upper passivation layer 112 may be improved. In addition, polymerization may occur between the dam structure 140 and the upper passivation layer 112, and in this case, the bonding force (e.g., adhesion) between the dam structure 140 and the upper passivation layer 112 may be further increased.

In some embodiments, the mounting substrate 110, the semiconductor chip 120, and the dam structure 140 may be encapsulated with an encapsulation layer or a mold layer.

An upper surface of the dam structure 140 may have segments having different (e.g., varying) vertical levels. Additionally, a segment may be planar and may be parallel to a major plane of the mounting substrate. For example, the upper surface of the dam structure 140 may include a first segment having a first vertical level and a second segment having a second vertical level that is higher than the first vertical level. For example, when a distance in the vertical direction (Z direction) between the upper surface 119 of the mounting substrate 110 and the first segment of the upper surface of the dam structure 140 is defined as a first distance and a distance in the vertical direction (Z direction) between the upper surface 119 of the mounting substrate 110 and the second segment of the upper surface of the dam structure 140 is defined as a second distance, the first distance may be about 20 μm to about 50 μm, and the difference between the second distance and the first distance may be between about 10 μm and about 100 μm.

The dam structure 140 may include a plurality of sidewalls having different vertical lengths. Here, the vertical length may mean a length in the vertical direction (Z direction) from the upper surface 119 of the mounting substrate 110. The dam structure 140 may include a low-sidewall having a relatively small vertical length and a high-sidewall having a relatively large vertical length. For example, the vertical length of the low-sidewall of the dam structure 140 may be between about 20 μm and about 50 μm, and the difference between the vertical length of the high-sidewall and the vertical length of the low-sidewall of the dam structure 140 may be between about 10 μm and about 100 μm. During the underfill process, the underfill material may be injected into a gap between the low-sidewall of the dam structure 140 and the semiconductor chip 120 through a nozzle, and spread along a gap between the semiconductor chip 120 and the mounting substrate 110. The high-sidewall of the dam structure 140 is in a portion, or location where overflow of the underfill material is likely to occur, thereby blocking the overflow of the underfill material. In general, there is often a problem in that voids may be formed in the underfill material layer 133 near an area where the underfill material overflows. However, according to example embodiments, because the overflow of the underfill material is prevented by the high-sidewall of the dam structure 140, it is possible to prevent the formation of voids in the underfill material layer 133. Accordingly, the reliability of the underfill process may be improved and the reliability of the semiconductor package 100 including the underfill material layer 133 may be improved.

In example embodiments, the dam structure 140 may include a lower dam 141 attached to the upper passivation layer 112 of the mounting substrate 110 and an upper dam 145 on the lower dam 141. The upper dam 145 may cover a portion of the lower dam 141 but may not cover another portion of the lower dam 141 (e.g., the upper dam 145 may cover a portion of the upper surface of the lower dam 141 less than the entire upper surface of the lower portion). The upper dam 145 may extend along a portion of the upper surface of the lower dam 141 and may not be disposed on another portion of the upper surface of the lower dam 141. The lower dam 141 may be configured to have the vertical length that allows an underfill to be formed (e.g., injected) in a space between the semiconductor chip 120 and the mounting substrate 110.

In some example embodiments, the dam structure 140 may be formed as a single structure (e.g., a homogenous, integral structure) having at least one dam wall with a segment of the at least one dam wall having a different vertical length from top to bottom from another segment of the at least one dam wall. Additionally, a dam structure 140 formed as a single structure may still be logically divided into an upper dam 145 and a lower dam 141 based on different vertical lengths of sections of the at least one dam wall. For example, a first portion of a dam structure 140 including material between the mounting substrate 110 and an upper surface of a first segment of the at least one wall may be considered to be a lower dam 141, and the remaining material disposed higher than the upper surface of the first segment of the at least one wall may be considered to be an upper dam 145.

The upper dam 145 and the lower dam 141 may each be formed of and/or include a solder resist material, epoxy resin, and/or polyimide. In example embodiments, the lower dam 141 may include the same material as that of the upper passivation layer 112 (e.g., solder resist). In example embodiments, the upper dam 145 may include the same material (e.g., solder resist) as the lower dam 141. In example embodiments, the material of the upper dam 145 and the material of the lower dam 141 may be different from each other.

In example embodiments, the vertical length H1 of the lower dam 141 may be between about 20 μm and about 50 μm. In example embodiments, the vertical length H2 of the upper dam 145 may be between about 10 μm and about 100 μm. In some example embodiments, the vertical length H1 of the lower dam 141 may be uniform for the entire upper surface of the lower dam 141. In some example embodiments, the vertical length H1 of the upper dam 145 may be uniform for the entire upper surface of the upper dam 145. In some example embodiments, the vertical length H1 of the lower dam 141 may be between about 17 percent and about 83 percent of the total height of the dam structure 140 (e.g., the total of H1 and H2).

The lower dam 141 may have a ring shape surrounding the semiconductor chip 120. The lower dam 141 may have a square ring shape. In more detail, the lower dam 141 may include a first lower sidewall 1411 facing the first side surface S1 of the semiconductor chip 120, a second lower sidewall 1412 facing the second side surface S2 of the semiconductor chip 120, a third lower sidewall 1413 facing the third side surface S3 of the semiconductor chip 120, and a fourth lower sidewall 1414 facing the fourth side surface S4 of the semiconductor chip 120. In a plan view, the first to fourth lower sidewalls 1411, 1412, 1413, and 1414 of the lower dam 141 may extend linearly, respectively.

The upper dam 145 may be disposed on some lower sidewalls of the first to fourth lower sidewalls 1411, 1412, 1413, and 1414 of the lower dam 141. For example, the upper dam 145 may be connected to one or more lower sidewalls among the first to third lower sidewalls 1411, 1412, and 1413, but may not extend along the further lower sidewall or be disposed on an upper surface of the fourth lower sidewall 1414. For example, the upper dam 145 may include a first upper sidewall 1451 on the first lower sidewall 1411 of the lower dam 141, a second upper sidewall 1452 on the second lower sidewall 1412 of the lower dam 141, and a third upper sidewall 1453 on the third lower sidewall 1413 of the lower dam 141. Because the upper dam 145 is not disposed on the fourth lower sidewall 1414 of the lower dam 141, the upper surface of the fourth lower sidewall 1414 may be exposed, and the fourth lower sidewall 1414 may define a portion of the upper surface of the dam structure 140.

The upper dam 145 may be disposed on a first portion of the upper surface of the lower dam 141 and not disposed on a second portion of the upper surface of the lower dam 141. For example, the upper dam 145 may be disposed on a first portion of the upper surface of the lower dam 142 including an upper surface of the first to third lower sidewalls 1411, 1412, and 1413, but not disposed on a second portion of the upper surface of the lower dam 142 including an upper surface of the fourth lower sidewall 1414. For example, the upper dam 145 may include a first upper sidewall 1451 disposed on an upper surface of the first lower sidewall 1411 of the lower dam 141, a second upper sidewall 1452 on an upper surface of the second lower sidewall 1412 of the lower dam 141, and a third upper sidewall 1453 disposed on an upper surface of the third lower sidewall 1413 of the lower dam 141.

The horizontal width of each wall of the dam structure 140 may be between about 40 μm and about 200 μm, between about 50 μm and about 180 μm, between about 60 μm and about 160 μm, between about 70 μm and about 140 μm, or between about 80 μm and about 120 μm. In the dam structure 140, the horizontal width may be defined as a horizontal distance between the outer and inner surfaces of each wall of the dam structure 140. An inner surface of the dam structure 140 may face the semiconductor chip 120 and may contact the underfill material layer 133. In example embodiments, the horizontal width W2 of the upper dam 145 and the horizontal width W1 of the lower dam 141 may be equal to each other. In example embodiments, the horizontal width W2 of the upper dam 145 and the horizontal width WI of the lower dam 141 may be different from each other. In example embodiments, the horizontal width W2 of the upper dam 145 may be greater than the horizontal width W1 of the lower dam 141.

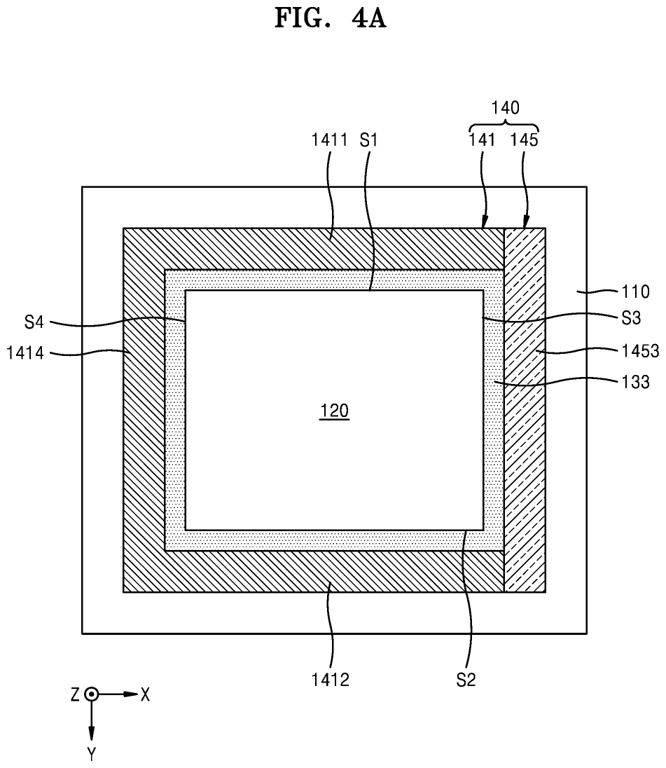

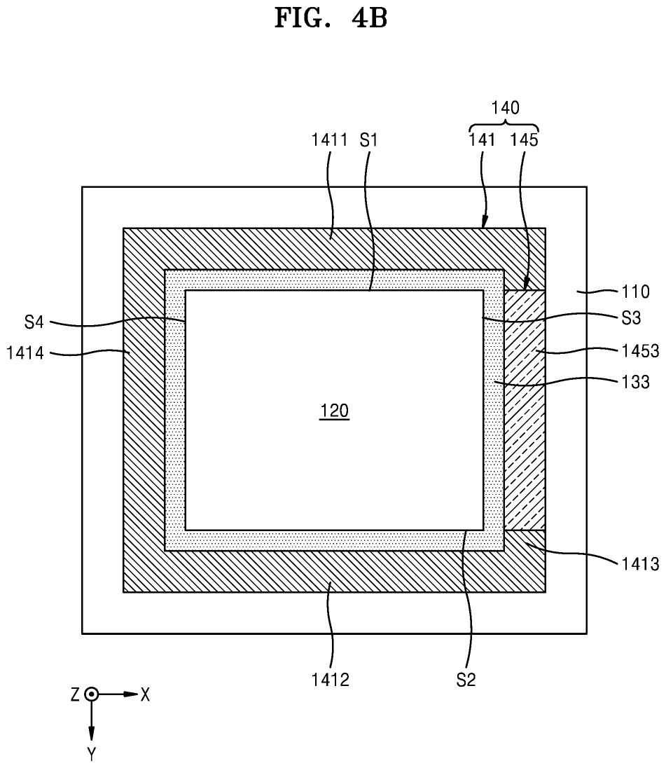

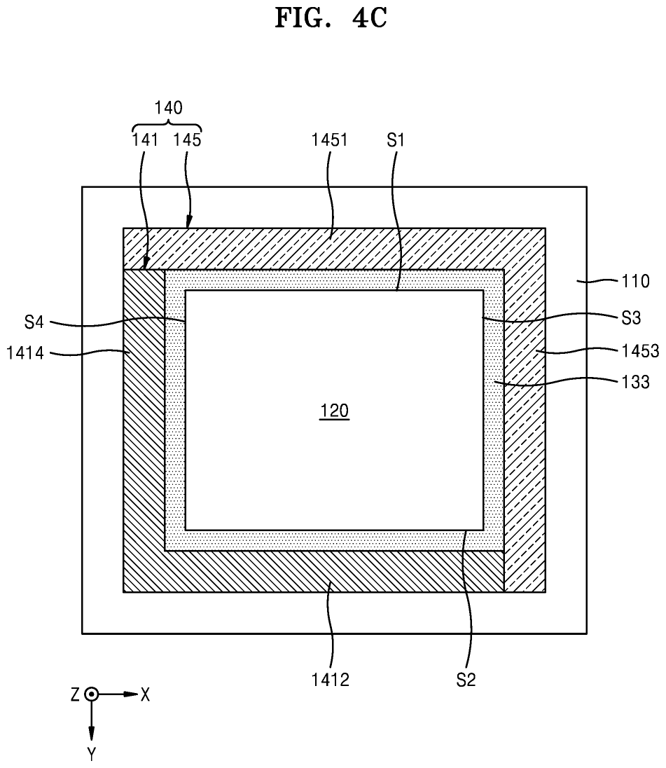

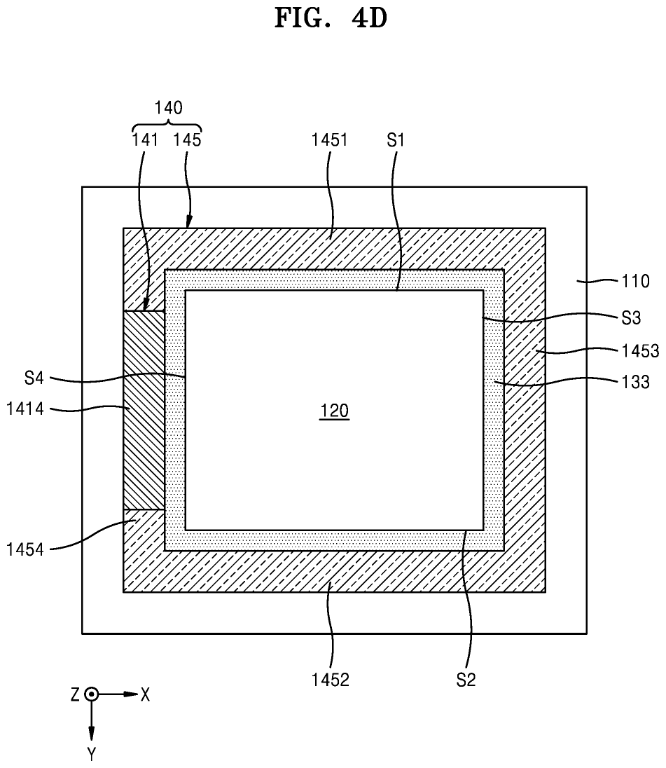

FIGS. 4A to 4D are plan views each illustrating a semiconductor package according to embodiments. Hereinafter, the semiconductor packages shown in FIGS. 4A to 4D are described, focusing on the differences from the semiconductor package 100 described with reference to FIGS. 1 to 3.

Referring to FIG. 4A, the upper dam 145 may be disposed only on one lower sidewall among the first to fourth lower sidewalls (see 1411, 1412, 1413, and 1414 in FIGS. 2 and 3) of the lower dam 141. For example, the upper dam 145 may be formed of a third upper sidewall 1453 on the third lower sidewall 1413 of the lower dam 141. The upper dam 145 is not disposed on an upper surface of the first lower sidewall 1411, an upper surface of the second lower sidewall 1412, and an upper surface of the fourth lower sidewall 1414 of the lower dam 141. The third upper sidewall 1453 may extend entirely along the complete length of the third lower sidewall 1413.

Referring to FIG. 4B, the third upper sidewall 1453 may extend along only a portion of the third lower sidewall 1413 (e.g., less than the full length). For example, the third upper sidewall 1453 may be disposed only on a central portion of the third lower sidewall 1413 in the second horizontal direction (Y direction).

Referring to FIG. 4C, the upper dam 145 may be disposed on two lower sidewalls among the first to fourth lower sidewalls (see 1411, 1412, 1413, and 1414 in FIGS. 2 and 3) of the lower dam 141. For example, the upper dam 145 may include a first upper sidewall 1451 on the first lower sidewall 1411 of the lower dam 141 and a third upper sidewall 1453 on the third lower sidewall 1413. The upper dam 145 is not disposed on an upper surface of and/or does not extend along the second lower sidewall 1412 and the fourth lower sidewall 1414 of the lower dam 141.

Referring to FIG. 4D, the upper dam 145 includes first to third upper sidewalls 1451, 1452, and 1453 disposed on the first to third lower sidewalls (see 1411, 1412, and 1413 in FIGS. 2 and 3) of the lower dam 141, and may include a fourth upper sidewall 1454 disposed on a portion of the fourth lower sidewall 1414 of the lower dam 141. The fourth upper sidewall 1454 may partially cover the fourth lower sidewall 1414. The fourth upper sidewall 1454 may not be disposed on a center portion of the fourth lower sidewall 1414 in the second horizontal direction (Y direction), but may be disposed on an edge portion of the fourth lower sidewall in the second horizontal direction (Y direction).

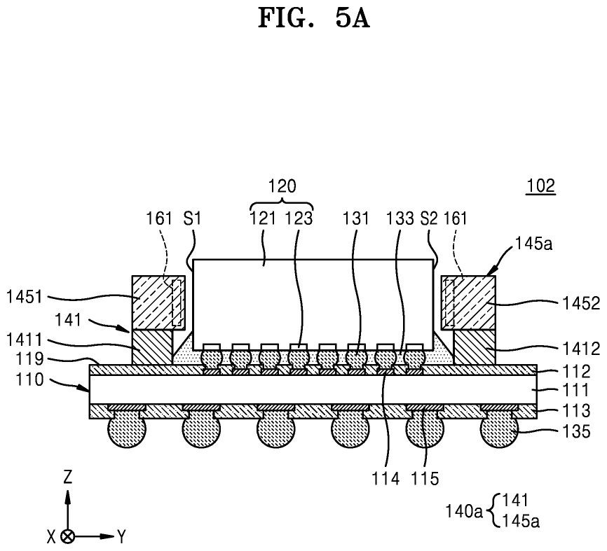

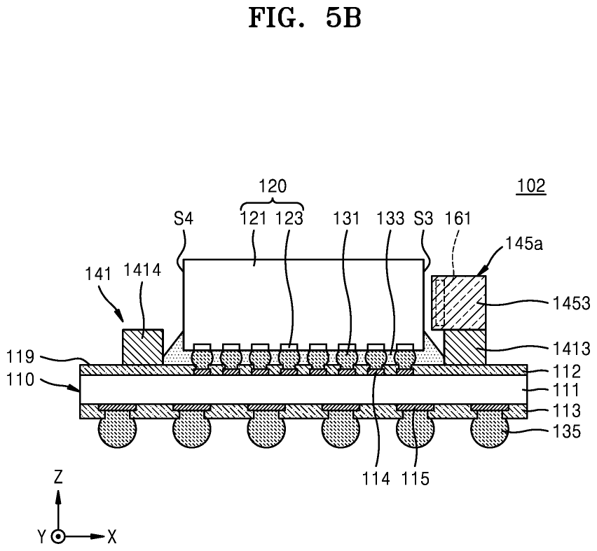

FIGS. 5A and 5B are cross-sectional views illustrating a semiconductor package 102 according to embodiments. FIGS. 5A and 5B show different cross-sections of the semiconductor package 102.

Referring to FIGS. 5A and 5B, in a dam structure 140a, a horizontal width of an upper dam 145a may be greater than a horizontal width of the lower dam 141. The upper dam 145a may include eaves 161 extending laterally (e.g., horizontally) from an inner surface of the lower dam 141 toward the semiconductor chip 120 to cover a gap between the lower dam 141 and the semiconductor chip 120. The eaves 161 have an overhang structure protruding from the inner surface of the lower dam 141 toward the semiconductor chip 120. The underfill material layer 133 may contact the eaves 161 of the upper dam 145a. The first to third upper sidewalls 1451, 1452, and 1453 of the upper dam 145a may each include eaves 161. As the upper dam 145a includes the eaves 161, the flow of the underfill material rising along the lower dam 141 may be more effectively suppressed. Accordingly, the overflow of the underfill material may be more effectively controlled.

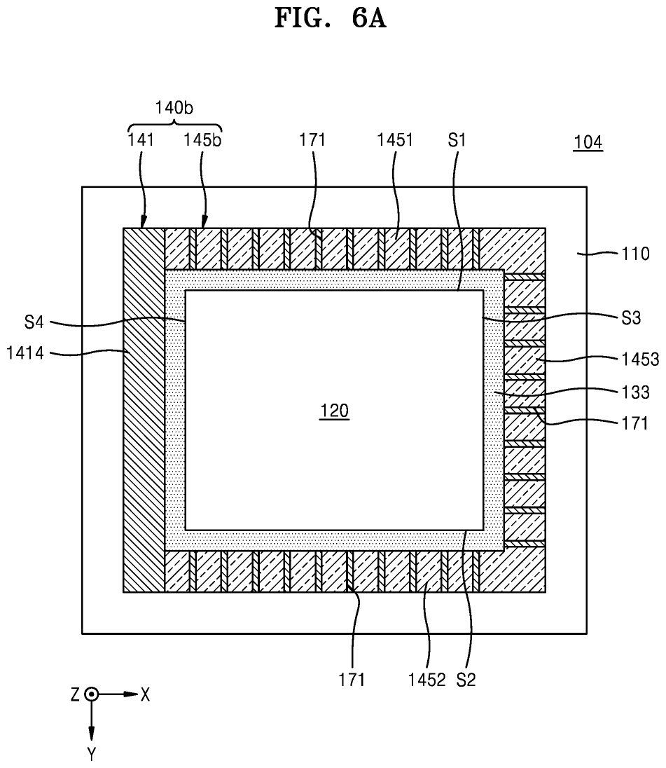

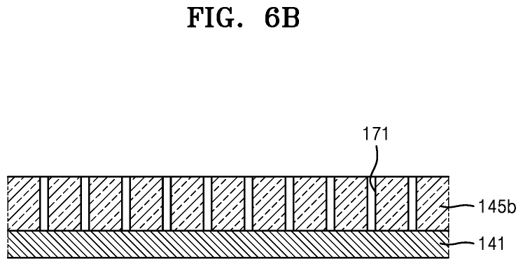

FIGS. 6A and 6B are diagrams illustrating a semiconductor package 104 according to embodiments. FIG. 6A is a plan view showing the semiconductor package 104, and FIG. 6B is a side view showing a portion of a dam structure 140b.

Referring to FIGS. 6A and 6B, in the dam structure 140b, an upper dam 145b may include a plurality of slits 171. Each of the plurality of slits 171 may be a groove vertically penetrating through the upper dam 145b. Alternatively, each of the plurality of slits 171 may extend from the upper surface toward the lower surface of the upper dam 145b, but may only partially penetrate the upper dam 145b. In a plan view, the plurality of slits 171 may linearly extend between the inner and outer surfaces of the upper dam 145b. The plurality of slits 171 may function as heat dissipation passages for the semiconductor chip 120, thereby improving heat dissipation characteristics of the semiconductor package 104. A horizontal width of each slit 171 may be between about 2 μm and about 20 μm, but is not limited thereto. The underfill material may have a predetermined viscosity selected so that the underfill material does not overflow to the outside of the dam structure 140b through the plurality of slits 171 of the upper dam 145b formed in a narrow width.

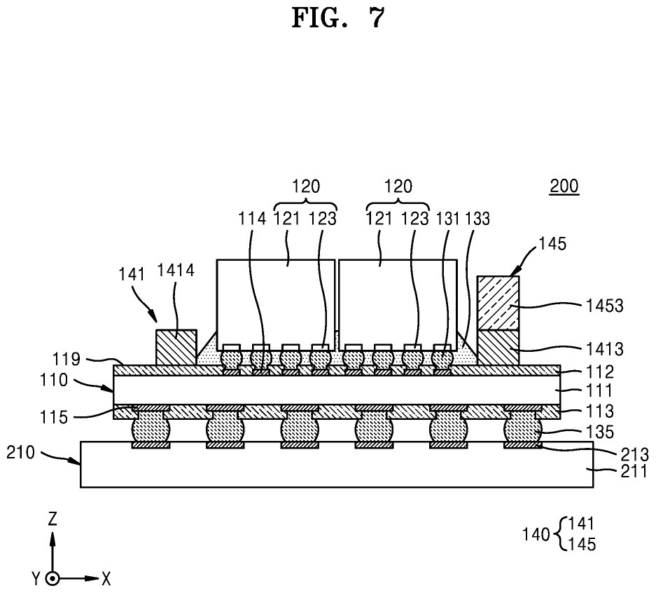

FIG. 7 is a cross-sectional view illustrating a semiconductor package 200 according to embodiments. Hereinafter, the semiconductor package 200 of FIG. 7 is described, focusing on the differences from the semiconductor package 100 described with reference to FIGS. 1 to 3.

Referring to FIG. 7, the semiconductor package 200 may include a plurality of semiconductor chips 120 mounted on a mounting substrate 110. The plurality of semiconductor chips 120 may be disposed side-by-side on the upper surface 119 of the mounting substrate 110. The plurality of semiconductor chips 120 may be electrically connected to each other through wiring lines of the mounting substrate 110. The underfill material layer 133 may fill a gap between each of the plurality of semiconductor chips 120 and the mounting substrate 110. The dam structure 140 may be disposed to surround a chip mounting area where the plurality of semiconductor chips 120 are disposed. The semiconductor package 200 may further include a lower substrate 210 disposed below the mounting substrate 110. The lower substrate 210 may be, for example, a PCB. The lower substrate 210 may include a core insulating layer 211 and connection pads 213 disposed on the core insulating layer 211. The connection pads 213 of the lower substrate 210 may be respectively connected to connection terminals 135. The lower substrate 210 and the mounting substrate 110 may be electrically and physically connected to each other through the connection terminals 135.

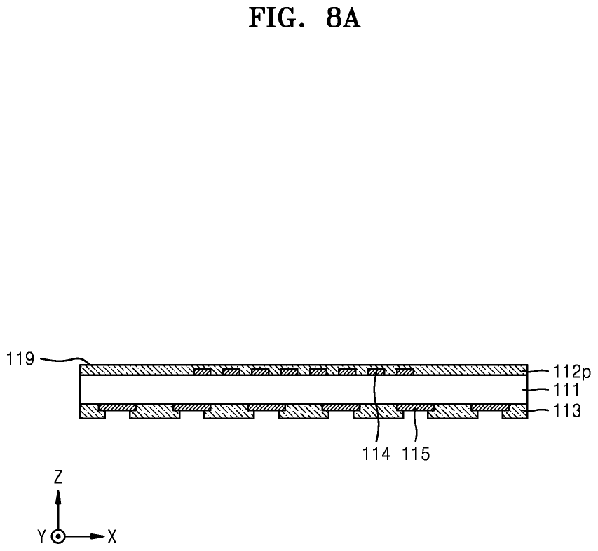

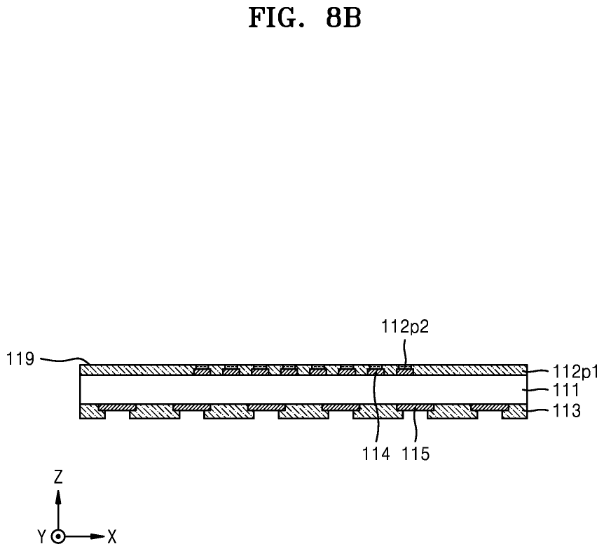

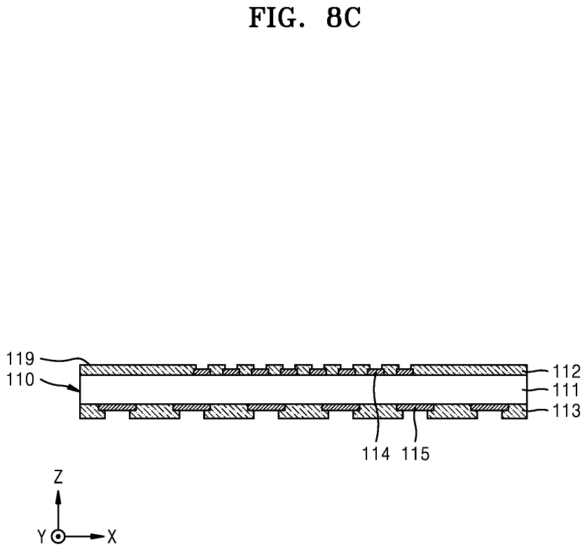

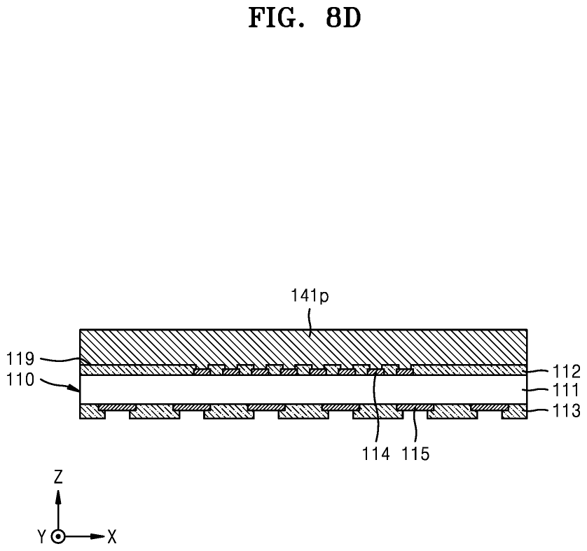

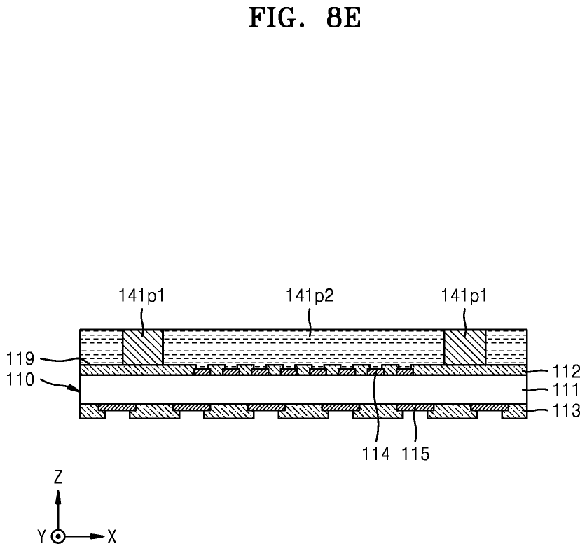

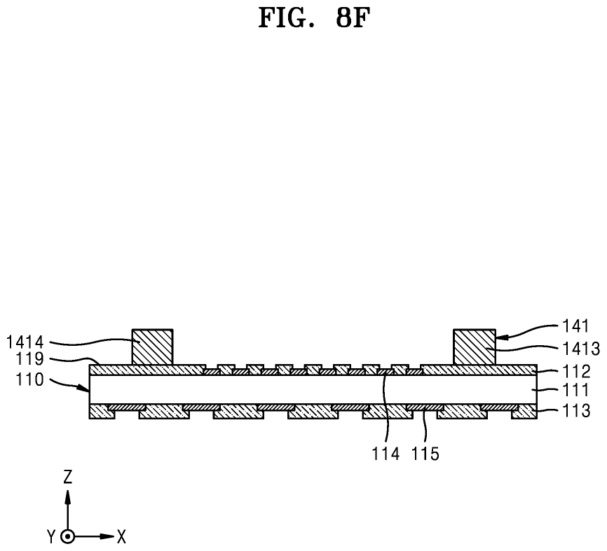

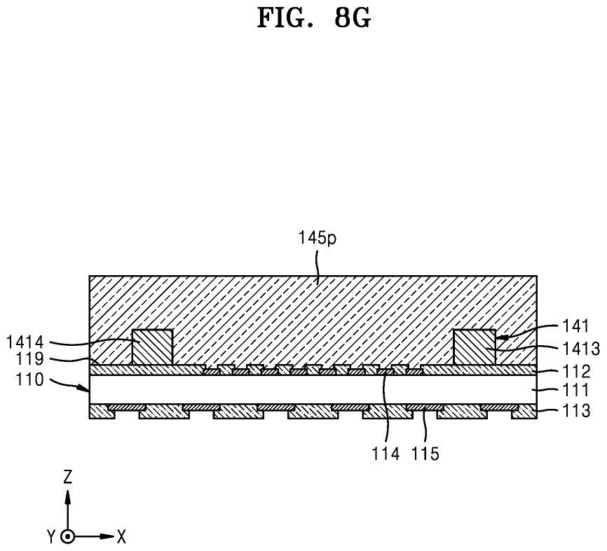

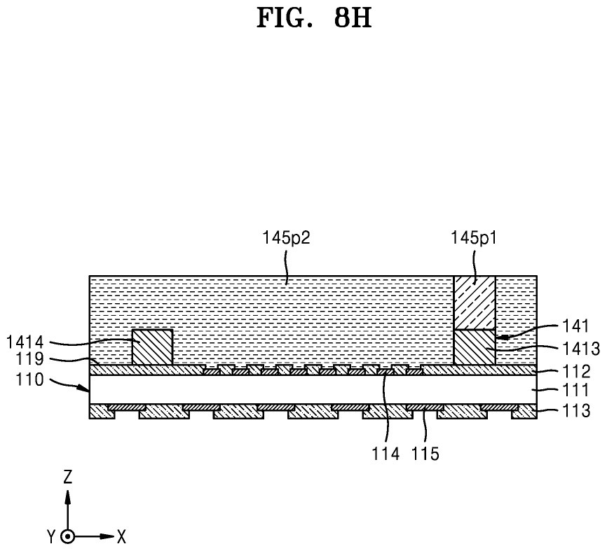

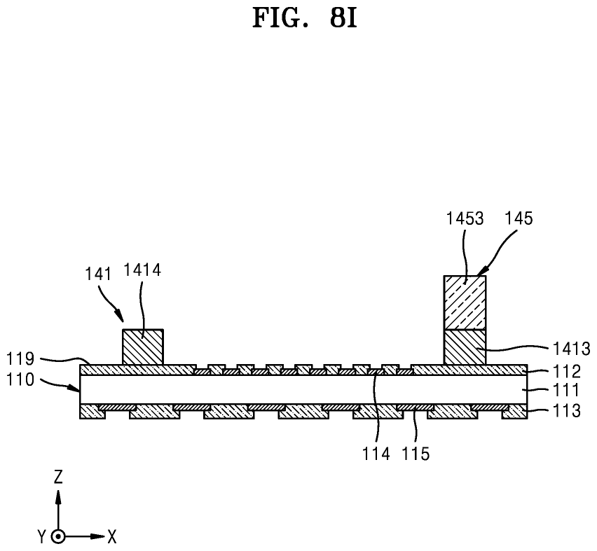

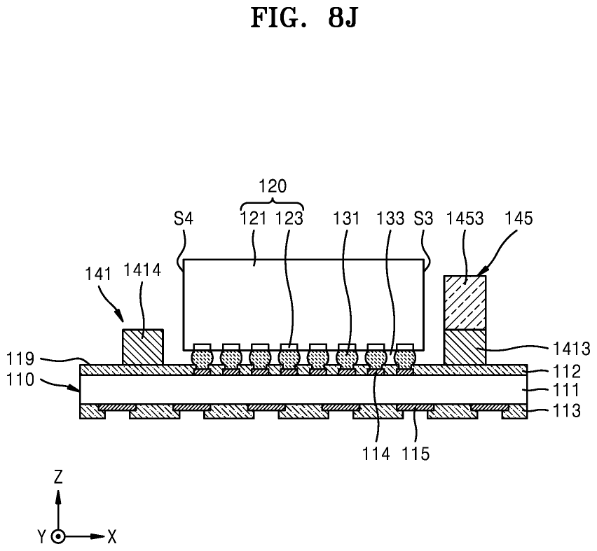

FIGS. 8A to 8J are cross-sectional views illustrating a method of manufacturing a semiconductor package, according to embodiments Hereinafter, an example of a manufacturing method of the semiconductor package 100 shown in FIGS. 1 to 3 is described with reference to FIGS. 8A to 8J.

Referring to FIG. 8A, a first material layer 112p is formed on the upper surface of a base layer 111. The first material layer 112p may include, for example, solder resist. The first material layer 112p may cover the upper surface of the base layer 111 and the upper connection pads 114. The first material layer 112p may be provided from dry film solder resist (DFSR) or a liquid solder resist material.

Referring to FIGS. 8A and 8B, an exposure process is performed on the first material layer 112p. As a result of the exposure process, the first material layer 112p may have an exposed area 112p2 exposed to light and a non-exposed area 112p1 not exposed to light.

Referring to FIGS. 8B and 8C, after the exposure process on the first material layer 112p, a developing process may be performed to remove the exposed area 112p2 of the first material layer 112p. The non-exposed area 112p1 of the first material layer 112p remaining after the developing process may become the upper passivation layer 112. The upper passivation layer 112 may include upper openings respectively exposing the upper connection pads 114. The base layer 111, the upper connection pads 114, the lower connection pads 115, the upper passivation layer 112, and the lower passivation layer 113 may constitute the mounting substrate 110.

Referring to FIG. 8D, a second material layer 141p is formed on the mounting substrate 110. The second material layer 141p may include, for example, solder resist. The second material layer 141p may cover the upper surface 119 of the mounting substrate 110. The second material layer 141p may be provided from DFSR or a liquid solder resist material.

Referring to FIGS. 8D and 8E, an exposure process is performed on the second material layer 141p. As a result of the exposure process, the second material layer 141p may have an exposed area 141p2 exposed to light and a non-exposed area 141p1 not exposed to light.

Referring to FIGS. 8E and 8F, after the exposure process on the second material layer 141p, a developing process may be performed to remove the exposed area 141p2 of the second material layer 141p. The non-exposed area 141p1 of the second material layer 141p remaining after the developing process may become the lower dam 141.

Referring to FIG. 8G, a third material layer 145p is formed on the mounting substrate 110. The third material layer 145p may include, for example, solder resist. The third material layer 145p may cover the mounting substrate 110 and the lower dam 141. The third material layer 145p may be provided from DFSR or a liquid solder resist material.

Referring to FIGS. 8G and 8H, an exposure process is performed on the third material layer 145p. As a result of the exposure process, the third material layer 145p may include an exposed area 145p2 exposed to light and a non-exposed area 145p1 not exposed to light.

Referring to FIGS. 8H and 8I, after the exposure process on the third material layer 145p, a developing process may be performed to remove the exposed area 145p2 of the third material layer 145p. The non-exposed area 145p1 of the third material layer 145p remaining after the developing process may become the upper dam 145. The upper dam 145 and the lower dam 141 may constitute the dam structure 140.

Referring to FIG. 8J, the semiconductor chip 120 is mounted on the mounting substrate 110. Using the chip connection bumps 131, the semiconductor chip 120 may be mounted on the mounting substrate 110.

Referring to FIG. 3, after the semiconductor chip 120 is mounted on the mounting substrate 110, an underfill process is performed to form the underfill material layer 133. The underfill material may be supplied onto the mounting substrate 110 through a nozzle. For example, the nozzle may be provided on the mounting substrate 110 through a gap between the fourth lower sidewall 1414 of the lower dam 141 corresponding to the low-sidewall of the dam structure 140 and the semiconductor chip 120. Because a high-sidewall of the dam structure 140 is disposed in a portion of the dam structure 140 where overflow of the underfill material is likely to occur, overflow of the underfill material may be prevented and formation of voids in the underfill material layer 133 may be prevented. Accordingly, the reliability of the underfill process may be improved and the reliability of the semiconductor package 100 including the underfill material layer 133 may be improved.

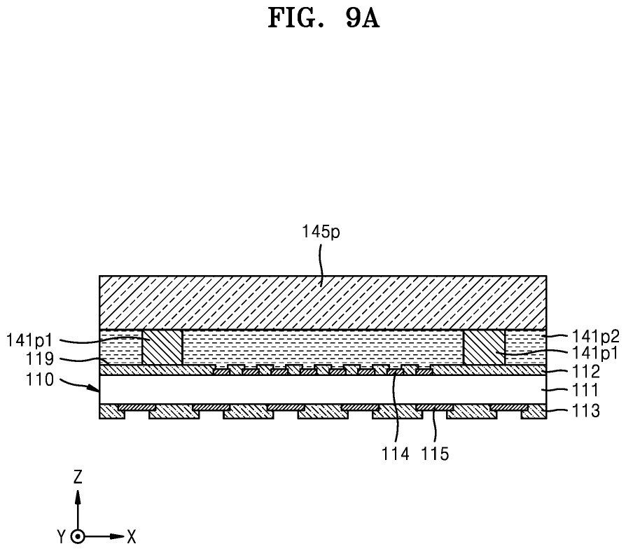

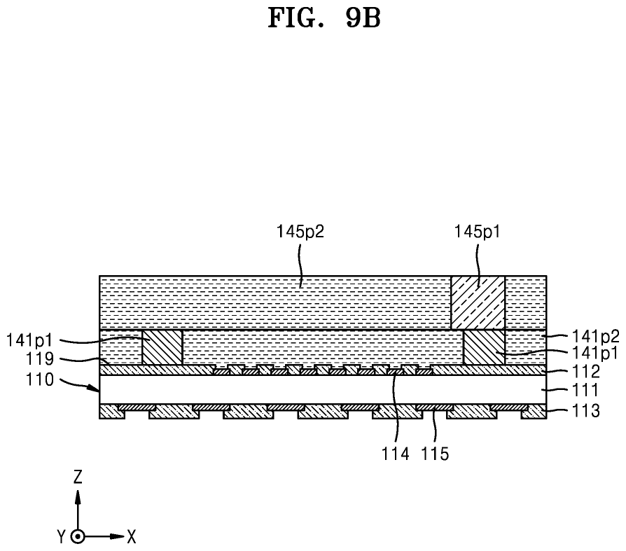

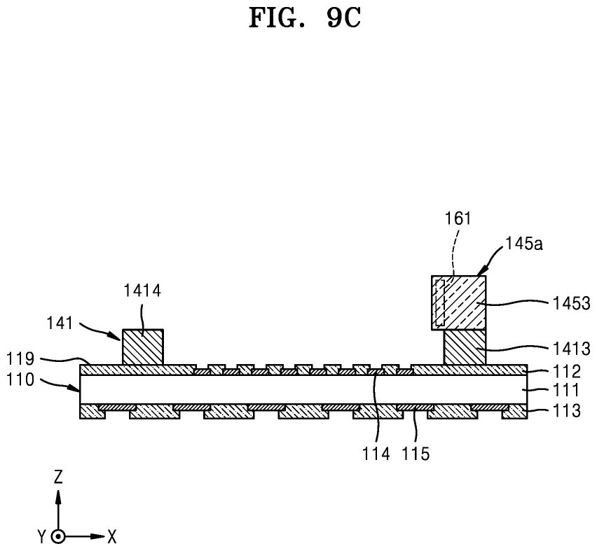

FIGS. 9A to 9C are cross-sectional views illustrating a method of manufacturing a semiconductor package, according to embodiments. Hereinafter, an example of a manufacturing method of the semiconductor package 102 shown in FIGS. 5A and 5B is described with reference to FIGS. 9A to 9C.

Referring to FIG. 9A, the structure shown in FIG. 8E is prepared, and a third material layer 145p is formed on the exposed area 141p2 and the non-exposed area 141p1 of the second material layer 141p of FIG. 8D. The third material layer 145p may include solder resist.

Referring to FIGS. 9A and 9B, an exposure process is performed on the third material layer 145p. As a result of the exposure process, the third material layer 145p may have an exposed area 145p2 exposed to light and a non-exposed area 145p1 not exposed to light.

Referring to FIGS. 9B and 9C, after the exposure process on the third material layer 145p, a developing process may be performed to remove the exposed area 141p2 of the second material layer 141p of FIG. 8D and the exposed area 145p2 of the third material layer 145p. The non-exposed area 141p1 of the second material layer 141p remaining after the developing process may become the lower dam 141, and a non-exposed area 145p1 of the third material layer 145p remaining after the developing process may become the upper dam 145. The upper dam 145 may be formed to have eaves 161 protruding laterally from the inner surface of the lower dam 141. The upper dam 145 and the lower dam 141 may constitute the dam structure 140.

Referring to FIG. 5A, after the dam structure 140 is formed, the semiconductor chip 120 may be mounted on the mounting substrate 110 and the underfill material layer 133 may be formed through an underfill process.

While the inventive concept has been particularly shown and described with reference to embodiments thereof, it will be understood that various changes in form and details may be made therein without departing from the spirit and scope of the following claims.

What is claimed is:

1. A semiconductor package comprising:
a substrate including a passivation layer;
a semiconductor chip mounted on the substrate;
an underfill material layer between the semiconductor chip and the substrate; and
a dam structure on the substrate and surrounding the semiconductor chip,
wherein a lower portion of the dam structure is in contact with the passivation layer and is formed of a material that is the same as a material forming the passivation layer, and
an upper surface of the dam structure includes a first segment at a first vertical level and a second segment at a second vertical level different from the first vertical level.

2. The semiconductor package of claim 1, wherein the lower portion of the dam structure and the passivation layer are formed of a solder resist.

3. The semiconductor package of claim 1,
wherein the dam structure includes
a lower dam having a ring-shape surrounding the semiconductor chip and formed of the same material as that of the passivation layer; and
an upper dam disposed on the lower dam and extending along a portion of the lower dam.

4. The semiconductor package of claim 3,
wherein the lower dam includes a first lower sidewall facing a first side of the semiconductor chip, a second lower sidewall facing a second side of the semiconductor chip, a third lower sidewall facing a third side of the semiconductor chip, and a fourth lower sidewall facing a fourth side of the semiconductor chip,
the upper dam extends along at least one of the first lower sidewall, the second lower sidewall, and the third lower sidewall of the lower dam, and
the upper dam does not extend along the fourth lower sidewall of the lower dam.

5. The semiconductor package of claim 3, wherein the lower dam and the upper dam are formed of the same material as each other.

6. The semiconductor package of claim 3, wherein the lower dam is formed of a different material than a material forming the upper dam.

7. The semiconductor package of claim 3, wherein the upper dam includes a lower sidewall, the upper dam includes an upper sidewall, and a width of the upper sidewall in a first direction parallel to an upper surface of the substrate is greater than a width of the lower sidewall in the first direction.

8. The semiconductor package of claim 3,
wherein the upper dam further includes eaves extending laterally from an inner surface of the lower dam toward the semiconductor chip to cover a portion of a gap between the lower dam and the semiconductor chip.

9. The semiconductor package of claim 3, wherein the upper dam includes a plurality of slits.

10. The semiconductor package of claim 1,
wherein a first distance between the first segment of the upper surface of the dam structure and an upper surface of the substrate is between about 20 μm and about 50 μm,
a second distance between the second segment of the upper surface of the dam structure and the upper surface of the substrate is greater than the first distance,
the difference between the second distance and the first distance is between about 10 μm and about 100 μm.

11. The semiconductor package of claim 1, wherein the dam structure includes a sidewall and a width of the sidewall in a first direction parallel to an upper surface of the substrate is between about 40 μm and about 200 μm.

12. The semiconductor package of claim 1, further comprising
chip connection bumps between the semiconductor chip and the substrate,
wherein the underfill material layer is in contact with the chip connection bumps and the dam structure.

13. A semiconductor package comprising:
a substrate;
a semiconductor chip mounted on the substrate;
an underfill material layer between the semiconductor chip and the substrate; and
a dam structure including a ring-shaped lower dam surrounding the semiconductor chip and an upper dam on the lower dam,
wherein the upper dam includes eaves covering a portion of a gap between the lower dam and the semiconductor chip.

14. The semiconductor package of claim 13, wherein the upper dam extends along a portion of the lower dam.

15. The semiconductor package of claim 13, wherein the lower dam and the upper dam are formed of a solder resist.

16. The semiconductor package of claim 13,
wherein the substrate includes
a base layer;
an upper passivation layer on an upper surface of the base layer; and
a lower passivation layer on a lower surface of the base layer,
wherein the lower dam is in contact with the upper passivation layer and is formed of the same material as the material forming the upper passivation layer.

17. A semiconductor package comprising:
a substrate including a base layer, connection pads on the base layer, and a passivation layer on the base layer;
chip connection bumps connected to the connection pads through openings of the passivation layer;
a semiconductor chip connected to the chip connection bumps;
an underfill material layer provided between the semiconductor chip and the substrate and surrounding the chip connection bumps; and
a dam structure on the substrate and surrounding the semiconductor chip, the dam structure including a lower dam attached to the passivation layer and an upper dam on the lower dam,
wherein an upper surface of the dam structure includes a plurality of segments at different vertical levels,
the lower dam includes a first lower sidewall facing a first side of the semiconductor chip, a second lower sidewall facing a second side of the semiconductor chip, a third lower sidewall facing a third side of the semiconductor chip, and a fourth lower sidewall facing a fourth side of the semiconductor chip,
the upper dam extends along at least one of the first lower sidewall, the second lower sidewall, and the third lower sidewall of the lower dam, and
the lower dam, the upper dam, and the passivation layer include the same material as each other.

18. The semiconductor package of claim 17, wherein an upper surface of the upper dam is at a first vertical level, an upper surface of the lower dam is at a second vertical level, the first vertical level is higher than the second vertical level, and the upper dam includes a first upper sidewall extending along the first lower sidewall of the lower dam, a second upper sidewall extending along the second lower sidewall of the lower dam, and a third upper sidewall extending along the third lower sidewall of the lower dam.

19. The semiconductor package of claim 18, wherein the upper dam further includes a fourth upper sidewall on a portion of the fourth lower sidewall of the lower dam.

20. The semiconductor package of claim 17, wherein the upper dam further includes eaves extending laterally from an inner surface of the upper dam toward the semiconductor chip to cover a portion of a gap between the lower dam and the semiconductor chip.
